(19) United States
(12) Patent Application Publication
(10) Pub. No.: US 2008/0116541 A1
(43) Pub. Date: May 22, 2008

(54) STRUCTURE FOR INTEGRATING AN RF SHIELD STRUCTURE IN A CARRIER SUBSTRATE

(75) Inventors: Mete Erturk, Alburgh, VT (US); Robert A. Groves, Highland, NY (US); Anthony K. Stamper, Williston, VT (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/561,451

(22) Filed: Nov. 20, 2006

(51) Int. Cl. H01L 23/552; H01L 21/02

(52) U.S. Cl. 257/531; 438/381; 257/E21.003; 257/E23.114

(57) ABSTRACT

A structure for shielding high frequency passive elements includes a first face of a semi-conductive substrate in parallel with a second face of a non-conductive substrate. The first face of the semi-conductive substrate is substantially parallel to a second face thereof. A passive element is disposed in the non-conductive substrate and is isolated from the second face of the non-conductive substrate. A plurality of conductive conduits disposed in the semi-conductive substrate extends from the first face to the second face thereof, each of the conduits isolated from one another by the semi-conductive substrate material and disposed substantially beneath the passive element. A ground plane disposed on the second face of the semi-conductive substrate electrically connects the conductive conduits disposed therein. An electrical connection between an electronic circuit in the semi-conductive substrate, the passive element and the ground plane holds the passive device and the ground plane at different potentials.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates generally to shielding and isolating high frequency passive elements, and more particularly to providing a method and system for integrating an RF (radio frequency) shield structure in a carrier substrate employing an array of conductive conduits or vias.

2. Description of the Related Art

The Back End of Line (BEOL) region in semiconductor device manufacturing refers to the portion of an integrated circuit device where components such as transistors, resistors, etc., are interconnected with wiring on a substrate or wafer. The BEOL region encompasses contacts, insulator materials, metal levels, and bonding sites for chip-to-package connections. Passive elements integrated in BEOL metallization formed over—semi-conductive substrates experience power loss due to electric field penetration into the semi-conductive substrate. At high frequencies, this electric field penetration causes displacement current to flow in the semi-conductive substrate causing power loss. The power loss experienced in the substrate results in a degradation of the quality factor (Q) of the passive element(s). This displacement current can also cause noise generation (crosstalk) in the semi-conductive substrate that may then be communicated to adjacent circuit elements, thereby degrading overall circuit performance.

A primary means of shielding and isolating BEOL passive elements from the semi-conductive substrate is to introduce a conductive RF shield between the passive element and the semi-conductive substrate. This conductive RF shield is electrically isolated from the semi-conductive substrate and is connected to a low-noise, low-impedance AC (alternating current) ground that is designed to collect the parasitic electric field generated by the passive element. However, this approach to shielding is problematic. Achieving a low-noise, low-impedance AC ground on-chip is, in general, difficult due to the fact that there are a finite number of off-chip connections that provide connectivity to AC ground, and these connections must be redistributed on-chip to the location of the various passive elements that require shielding and isolation. The AC ground redistribution introduces additional inductance and resistance between the off-chip AC ground and the various RF shields, and also consumes valuable space that could be utilized for additional wiring and circuit functions. The additional inductance and resistance will also cause the RF shields to be at an uncontrolled potential with respect to the passive elements degrading their shielding effectiveness.

Common passive elements found in BEOL constructs employed in high frequency circuits such as low noise amplifiers (LNA), voltage controlled oscillators (VCO), tuned circuits, impedance matching networks, etc. are integrated spiral inductors. A key inductor performance metric is Q, which is the ratio of the inductor's ability to store energy to its power dissipating behavior. As a general rule, a high Q is required in high frequency tuned circuit applications, and is achieved by minimizing parasitic power losses. Various design techniques have been utilized to increase inductor Q. Some techniques concentrate on decreasing series resistive losses in the inductor metal, while others concentrate on reducing substrate related losses. The techniques for reducing substrate losses related to inductors fall into two broad categories: altering the material properties of the substrate to reduce loss, and shielding the inductor from interacting with the substrate.

A common technique for shielding a passive element such as an inductor is to implement a Faraday shield between the inductor and the substrate (Yue, C. P.; Wong, S. S., “On-chip spiral inductors with patterned ground shields for Si-based RF ICs,” Solid-State Circuits, IEEE Journal of, vol. 33, no. 5, pp. 743-752, May 1998). The purpose of the Faraday shield is to capture, and shunt to ground, the parasitic electric field of the inductor without disturbing the inductor's magnetic field. Placing a thin conductive sheet underneath the inductor that is connected to ground typically accomplishes this. The thin conductive sheet must be cut into pieces in some fashion to eliminate currents induced by the primary magnetic field of the inductor. These parasitic currents are generally called eddy currents and follow Lenz's law, causing current to flow in the conductive sheet underneath the inductor in a direction opposite to the direction of current flow in the inductor. A common technique to combat the parasitic currents places strips of conductive material under the inductor oriented in a radial fashion and tied together in the center or at the periphery. This “patterned ground shield” is then connected to a low impedance ground connection. Various conductive materials have been used to realize this shield: silicided diffusion, silicided polysilicon, and interconnect metal. Other arrangements of conductors can be used to realize a Faraday shield as well. However the “patterned ground shield” technique also suffers from the previously mentioned additional inductance and resistance present between the off-chip AC ground, which reduces the effectiveness of the shield.

FIGS. 1 and 2 are perspective views of prior art implementations of ground planes that provide RF shielding and isolation for passive elements connected to an integrated circuit.

In FIG. 1 a multilayer integrated circuit assembly 100 comprising a passive element 110 disposed in a non-conductive substrate 120 (for example, silicon dioxide), and an active circuit configuration 130 disposed in a semi-conductive substrate 140 (for example, silicon) are connected to each other via electrical interconnection 150. An RF shield 160 is connected to the active circuit configuration 130 by electrical interconnection 170. The RF shield 160 and the active circuit configuration 130 are also connected to an external AC ground potential through I/O (input/output) port 180. The AC ground potential is maintained on a conductive metal plane 190 that forms the bottom portion of the semi-conductive substrate 140. An electronic package (not shown) encapsulates integrated circuit assembly 100 and provides connections for the AC ground potential, as well as providing connectivity between the integrated circuit assembly 100 and external circuits and systems (not shown). The RF shield 160 is located substantially beneath the passive element 110, and is disposed in the non-conductive substrate 120. The RF shield 160 is typically realized using a high conductivity material (for example, tungsten, aluminum, copper, or gold). The RF shield 160 (AC ground) has a different electrical potential than the passive element 110. The potential difference existing between passive element 110 and the RF shield 160 causes the parasitic electric field that originates from passive element 110 to terminate on the RF shield 160. In the absence of the RF shield 160, the parasitic electric field would otherwise penetrate the semi-conductive substrate 140 and induce displacement currents to flow, thereby introducing power loss and noise injection into the semi-conductive substrate 140. The injected noise could travel through semi-conductive substrate 140 and reach the active circuit configuration 130 (or other adjacent electronic circuits—not shown), negatively impacting circuit performance. The RF shield 160 receives the parasitic electric field of the passive element 110 and returns it to the ground AC potential by the low impedance electrical interconnection 170 and I/O port 180, thereby limiting power loss and noise injection into the semi-conductive substrate 140.

FIG. 2 depicts an integrated circuit assembly 200 of similar configuration to FIG. 1, with the passive element 110 replaced with a square spiral inductor 210 disposed in a non-conductive substrate 220, and the RF Shield 160 replaced with an RF shield 260 also disposed in the non-conductive substrate 220. The RF shield 260 consists of a metallized layer divided into conductive strips that run perpendicular to the current flow in the square spiral inductor 210. The conductive strips, of the RF shield 260, are all electrically connected together along diagonal lines running from corner to corner and to electrical interconnection 270, which makes connection with I/O port 280 that provides AC ground potential (as maintained on ground plane 290, which serves the same function as ground plane 190 in FIG. 1) to both the active circuit configuration 230 (disposed on semi-conductive substrate 240) and the RF shield 260. The arrangement of conductive strips in the RF shield 260 provides a termination point for the parasitic electric field radiating from the square spiral inductor 210, and prevents the parasitic electric field from penetrating into the semi-conductive substrate 240, thereby improving Q and circuit performance and minimizing noise injection. The arrangement of the conductive strips in the RF shield 260 prevents interference with the primary magnetic field of the square spiral inductor 210.

The disadvantages of the prior art implementations of FIG. 1 and FIG. 2 arise in the realization of the electrical interconnection (170, 270) and the I/O port (180, 280) that can consist of connections such as wirebond pads or flip-chip interconnect. The number of potential I/O ports (180, 280) is limited, and there can be an extended distance between the RF shield (160, 260) and the nearest I/O port (180, 280), resulting in electrical interconnections (170, 270) having an excessive length that contributes to a high resistance and inductance. The high resistance and inductance causes the RF shield (160, 260) to be at a different electrical potential than the potential of the AC ground that is related to the active circuit configuration (130, 230). The resultant AC ground potential difference degrades the effectiveness of the RF shield (160, 260). In addition, the electrical interconnections (170, 270) and I/O ports (180, 280) consume valuable real estate on the semi-conductive substrate (140, 240), thereby reducing the achievable density of circuit function.

### SUMMARY OF THE INVENTION

Embodiments of the present invention comprise a structure for shielding high frequency passive elements disposed above a semi-conductive substrate configured for integrated circuit formation therein. The semi-conductive substrate having a first and a second face, with the second face being disposed substantially parallel to the first face. A non-conductive substrate having a first and a second face, the second face being disposed substantially parallel to the first face. The non-conductive substrate is placed on top of the semi-conductive substrate, with the first face of the semi-conductive substrate in parallel contact with the second face of the non-conductive substrate. A passive element disposed in the non-conductive substrate and isolated from the second face of the non-conductive substrate; an electronic circuit disposed in the semi-conductive substrate; a plurality of conductive conduits disposed in the semi-conductive substrate extending from the first face to the second face of the semi-conductive substrate, each of the conductive conduits being isolated from the neighboring conductive conduits by the material comprising the semi-conductive substrate and disposed substantially beneath the passive element; a ground plane disposed on the second face of the semi-conductive substrate, the ground plane electrically connecting the conductive conduits disposed in the semi-conductive substrate; and an electrical connection between the electronic circuit, the passive element and the ground plane, such that the passive device and the ground plane are held at different electrical potentials.

A method for implementing the RF shielding structure is also provided. The method comprises forming a semi-conductive substrate configured for integrated circuit formation therein, the semi-conductive substrate having a first and a second face, with the second face being disposed substantially parallel to said first face; forming a plurality of conductive conduits disposed in the semi-conductive substrate that extend from the first face to the second face of the semi-conductive substrate, with each of the conductive conduits being isolated from the neighboring conductive conduits by the material comprising the semi-conductive substrate; forming an integrated circuit in the semi-conductive substrate; forming a non-conductive substrate having a first and a second face, the second face being disposed substantially parallel to the first face; disposing the non-conductive substrate on top of the semi-conductive substrate, wherein the first face of the semi-conductive substrate is in parallel contact with the second face of the non-conductive substrate; disposing a passive element in the non-conductive substrate so as to be isolated from the second face of the non-conductive substrate, wherein the passive element is substantially above the plurality of conductive conduits; forming a metal layer ground plane disposed on the second face of the semi-conductive substrate, the ground plane electrically connecting the conductive conduits disposed in the semi-conductive substrate; and forming an electrical connection between the electronic circuit, the passive element and the metal layer ground plane, such that the passive element and the second metal ground plane are held at different electrical potentials.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### Technical Effects

As a result of the summarized invention, a solution is technically achieved in which RF shielding between a passive element and an active circuit is enhanced by the elimination of the additional inductance and resistance present between off-chip AC ground and the RF shield ground potential. The enhanced RF shielding is realized with an array of conductive conduits/vias that extend from the grounding plane of the circuit assembly. As a result the AC ground potential difference from that of the RF shield potential, that degrades the effectiveness of the RF shield, has been eliminated. In addition, electrical interconnections and I/O ports that consume valuable real estate on the circuit substrate can be further minimized with the present invention, thereby increasing the achievable density of circuit layouts.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a perspective view of a prior art implementation of a solid metal ground plane underneath a generic passive element connected to an active circuit.

FIG. 2 is a perspective view of a prior art implementation of a patterned metal ground plane underneath a square spiral inductor connected to an active circuit.

FIG. 3 is a perspective view of an array of conductive conduits/vias that form a RF shield underneath a generic passive element connected to an active circuit according to an embodiment of the present invention.

FIG. 4 is a perspective view of an array of conductive conduits/vias that form a RF shield underneath a square spiral inductor connected to an active circuit according to an embodiment of the present invention.

FIG. 5 is a perspective view of an array of oblong or rectangular conductive conduits/vias that form a RF shield underneath an octagonal, symmetric inductor connected to an active circuit according to an embodiment of the present invention.

FIG. 6 is a perspective view of an array of oblong or rectangular conductive conduits/vias that form a RF shield underneath an octagonal, symmetric inductor intended for differential operation connected to an active circuit according to an embodiment of the present invention.

FIG. 7 is a perspective view of an array of conductive conduits/vias that form a RF shield underneath a generic passive element connected to an active circuit, while also providing a means for eliminating the external AC ground I/O port for the active circuit configuration according to an embodiment of the present invention.

The detailed description explains the preferred embodiments of the invention, together with advantages and features, by way of example with reference to the drawings.

### DETAILED DESCRIPTION OF SPECIFIC EMBODIMENTS

Embodiments of the present invention provide a structure and method for shielding high frequency passive elements realized above a semi-conductive substrate, and is directed to addressing or at least reducing, the effects of one or more of the problem set forth above. The structure includes two substrates for fabricating integrated circuits, a bottom semi-conductive substrate and a top non-conductive substrate over the bottom substrate. The bottom substrate contains passive and/or active elements designed to realize a circuit function. The top substrate contains one or more passive elements that are utilized to achieve the circuit function. A plurality of metal conduits/vias (for example, copper, tungsten) is disposed in the semi-conductive substrate extending from one face to the other and appearing substantially beneath the passive element(s) in the non-conducting substrate. A metal ground plane is disposed on the bottom face of the semi-conductive substrate and electrically connects all of the metal conduits. The circuit makes connection to the passive element(s) and the metal ground plane such that parasitic electric field from the passive element(s) is channeled through the metal conduits and back into the circuit.

The present invention provides a method of creating an integrated RF shield utilizing conductive metal conduits that extend through a semi-conductive substrate to a conductive ground plane existing at the backside of the substrate. The semi-conductive substrate provides a vehicle for realizing integrated circuits, while a non-conductive substrate above contains BEOL passive elements in addition to metal interconnections used to connect various circuit elements. The semi-conductive substrate generally has a resistivity from about 0.1 Ω-cm to about 100 Ω-cm. The shield is designed to provide isolation between the BEOL passive element(s) and the semi-conductive substrate, decreasing the coupling of noise between circuit elements in the semi-conductive substrate and decreasing power loss. These conductive metal conduits (thru-wafer vias) are significantly more conductive (for example, copper, tungsten) than the semi-conductive substrate (for example, silicon) and provide a preferential path for capacitively coupled current existing between the passive elements and the semi-conductor substrate to flow to ground. The top surface of these vias includes a highly conductive metal, which can take the place of a metal RF shield created from a BEOL interconnect layer, as in the prior art, with the added advantage of connecting directly to the metal ground plane at the bottom of the semi-conductive substrate. The conductive metal conduits or vias are either completely filled with conductive material (for example copper, tungsten), or only have their sidewalls plated with conductive material. The conductive metal conduits have a smallest cross-sectional dimension that generally ranges from about 1 um to about 5 um. A plurality of these thru-wafer vias are arranged underneath a BEOL passive element (or extending beyond the boundaries of the passive element by approximately 5 um) with all of the vias being connected together with a metal at the bottom of the semi-conductive substrate causing all of the vias to be held at the same ground potential.

The present invention embodiments provide for an arrangement of the thru-wafer vias underneath the BEOL passive element that is dependent on the function of both the passive element and the integrated circuit. Non-inductive passive elements (e.g. wirebond pads, metal-insulator-metal capacitors, metal resistors, etc.) benefit from a regular array of thru-wafer vias with small circular or square cross-sectional areas, while inductive passive elements derive more benefit from thru-wafer vias with an oblong or rectangular cross-sectional area oriented perpendicular to the flow of current in the inductor. Integrated circuits that provide a differential signal to an inductive element that is symmetrically designed achieve performance enhancement from oblong or rectangular vias with exceptionally long and narrow cross-sections oriented with their long dimension perpendicular to the line of symmetry of the inductor.

For a passive element such as an inductor, transformer, or other magnetically coupled element, the conductive conduits may have a substantially oblong or rectangular cross-section such that the long dimension of the conductive conduit does not exceed ½ the long dimension of the passive element, while the short dimension ranges from about 1 um to about 5 um.

In an instance where the passive element is intended to have a controlled self inductance or internal mutual inductance, and the passive element is connected to an electronic circuit such that the potential on a first terminal of the passive element is approximately 180 degrees out of phase with the potential on a second terminal of the passive device, the conductive conduits can each have a substantially oblong or rectangular cross-section such that the long dimension of the conductive conduits exceeds the long dimension of the passive element by approximately 5 um, while the short dimension of the conductive conduits ranges from about 1 um to about 5 um. In addition, if the passive element is constructed such that the impedance of the first terminal is substantially equal to the impedance of the second terminal, and a line of symmetry exists through a centerline of the passive element, the conductive conduits are disposed such that their longest dimension is substantially perpendicular to the passive element's line of symmetry.

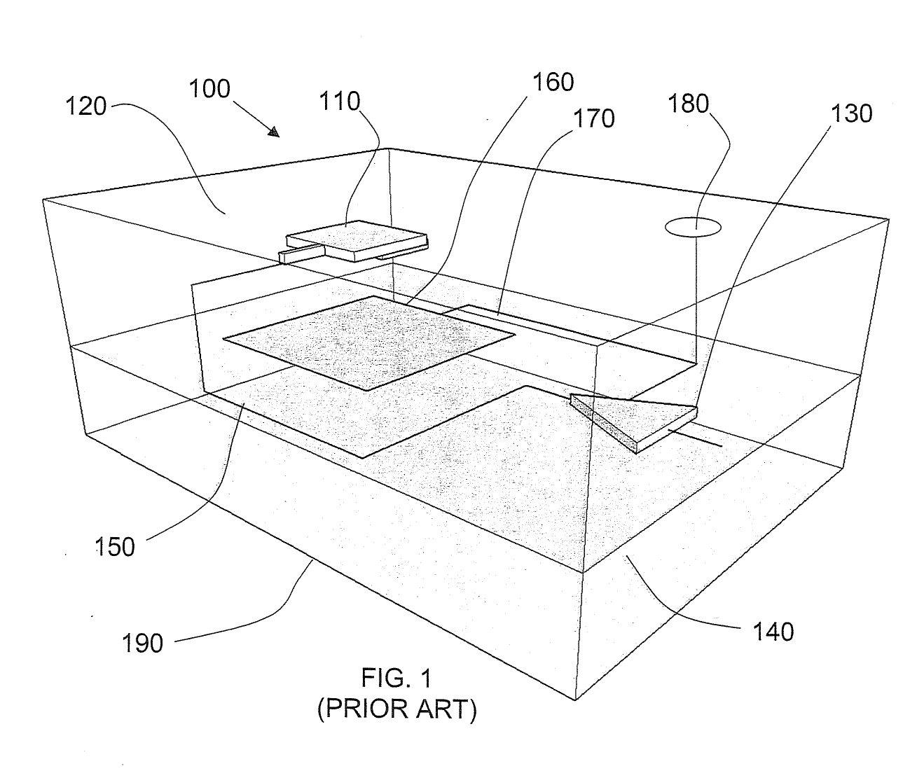

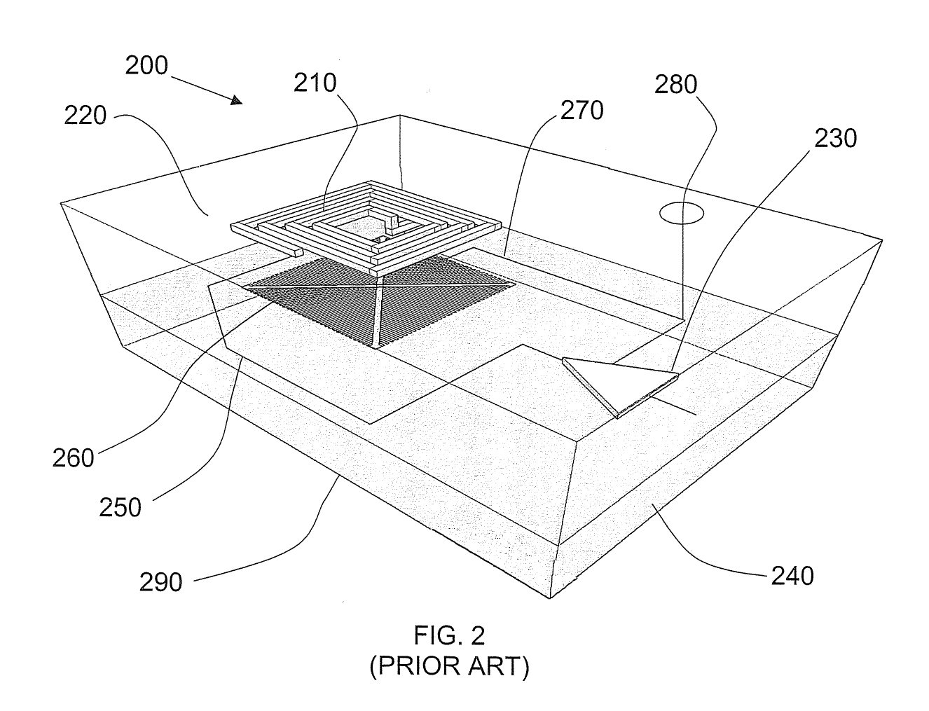

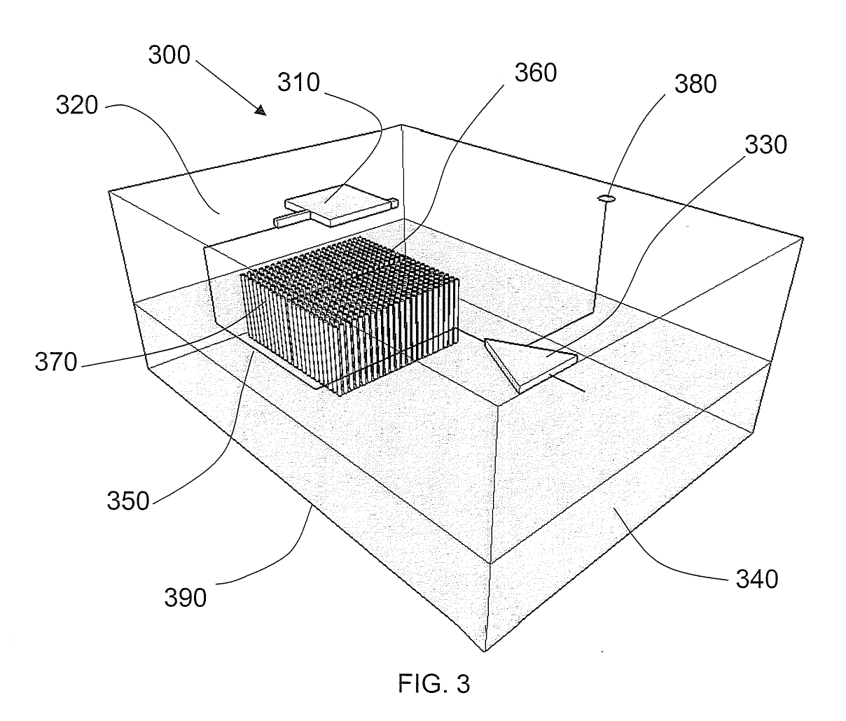

FIG. 3 illustrates an embodiment of an integrated circuit assembly 300 of the present invention utilizing through wafer vias for realizing improved RF shielding and isolation of a generic passive element 310. The generic passive element 310 is disposed in a non-conductive substrate 320 of a similar geometry to that of FIG. 1, and has an electrical interconnection 350 to an active circuit configuration 330. The RF shield 360 is formed by an array of metal conduits/conductive vias 370 arranged in a semi-conductive substrate 340. The array of conductive vias 370 has substantially equal spacing, and each of the conductive vias 370 are isolated from each other by the semi-conductive substrate 340. The cross-section of the conductive vias 370 that are depicted in FIG. 3 are circular; however other cross-section shapes such as square may be utilized depending on processing requirements of the conductive vias 370. The array of conductive vias 370 extend from the bottom ground plane 390 of the semi-conductive substrate 340 to the top surface of the semi-conductive substrate 340 that also supports active circuit configuration 330. The array of conductive vias 370 form RF shield 360, and are positioned substantially below the generic passive element 310, and occupy an area of similar dimensions to the generic passive element 310. The active circuit configuration 330 is connected through electrical interconnection 380 to the AC ground potential that is maintained on ground plane 390 and RF shield 360. The top surface of the array of conductive vias 370 provides an RF shielding function to the passive element 310. The parasitic electric field emanating from the passive element 310 terminates on the top surface of the array of conductive vias 370 instead of penetrating the semi-conductive substrate 340. This causes a reduction in noise injection into the semi-conductive substrate 340 and reduced power loss. The reduced noise injection and power loss enhance the performance of the active circuit configuration 330. It should be noted that the requirement for a dedicated electrical connection to establish a common internal AC ground between the RF shield 360 and active circuit 330 (e.g. electrical connections 170, 270 in FIG. 1 and FIG. 2, respectively) has been eliminated with the present invention embodiments. The elimination of the dedicated AC ground contributes to the minimization of the difference in electrical potential between the RF shield and the active circuit, as well as reducing wiring complexity, I/O requirements, and real estate usage.

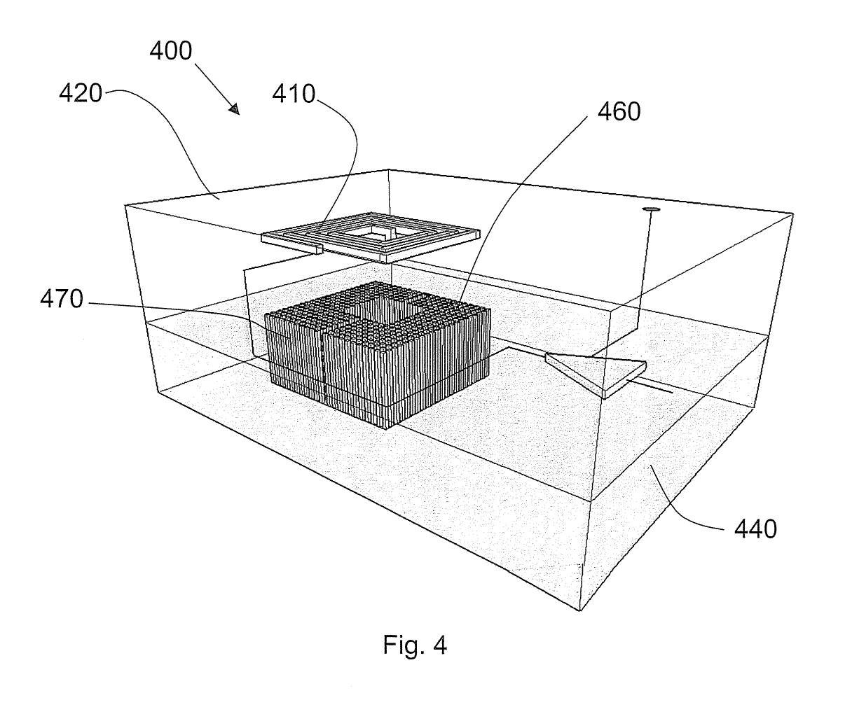

FIG. 4 illustrates an embodiment of an integrated circuit assembly 400 of the present invention utilizing through wafer vias for realizing an improved RF shielding and isolation of a square spiral inductor 410 disposed on a non-conductive substrate 420. The RF shield 460 includes a conductive array of vias 470 that form an irregular pattern with some regions of low density (corresponding to the center portion of the square spiral inductor 410), and regions of higher density (edge region of the square spiral inductor 410). The combination of high and low density regions provides a performance advantage for providing a RF shield for passive elements with various geometries and varying electric field strengths. In addition, the variation in the density of the array of vias 470 provides for enhanced structural rigidity in the semi-conductive substrate 440.

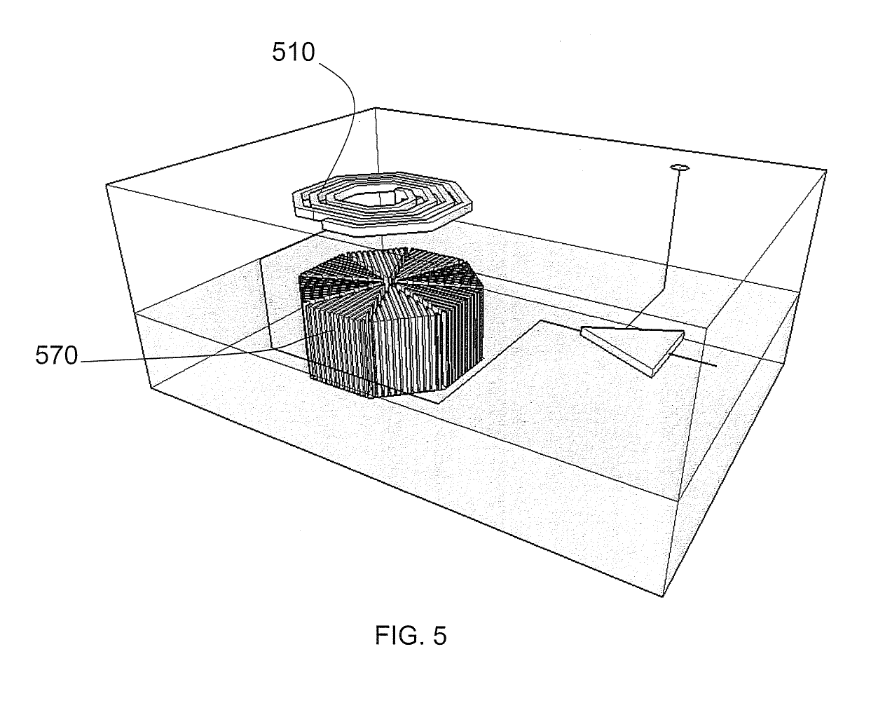

In FIG. 5 the conductive conduits/vias are of an oblong or rectangular shape, and the array of conductive conduits/vias 570 are arranged so as to be perpendicular to the current flow within the passive device octagonal inductor 510.

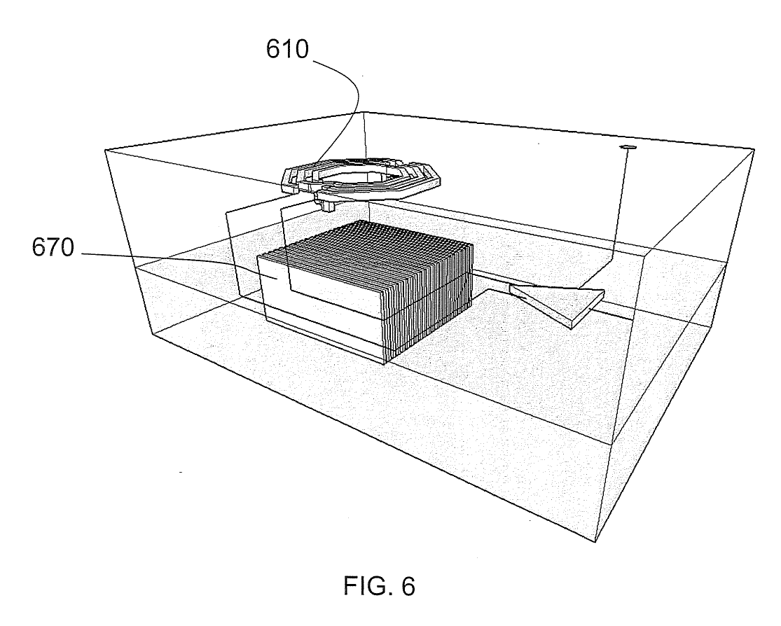

In FIG. 6 the conductive conduits/vias are of an oblong or rectangular shape, and the array of conductive conduits/vias 670 are arranged so as to be perpendicular to the current flow within the passive device 610 that is a symmetric inductor for differential operation.

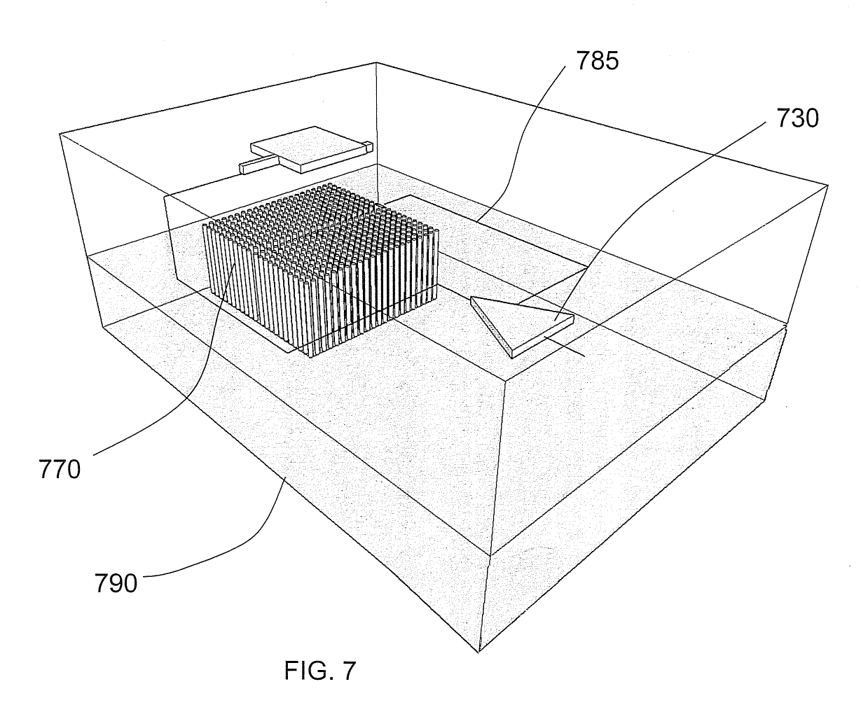

FIG. 7 is an implementation of an embodiment of the present invention, which facilitates the elimination of the AC ground I/O port (180 in FIG. 1) for the active circuit configuration. The I/O port (for example 180 in FIG. 1) can consist of connections such as wire bond pad or flip-chip interconnect. As indicated previously, the number of potential I/O ports is limited, and there can be an extended distance between the RF shield (160) and the nearest I/O port, resulting in electrical interconnections (170) having an excessive length that contributes to a high resistance and inductance. The high resistance and inductance causes the RF shield to be at a different electrical potential than the potential of the AC ground that is related to the active circuit configuration (130). The resultant AC ground potential difference degrades the effectiveness of the RF shield. In addition, the electrical interconnections (170) and I/O ports consume valuable real estate on the semi-conductive substrate (140), thereby reducing the achievable density of circuit function. However, by utilizing the AC ground potential of the array of conductive vias 770, the I/O port supplying the active circuit configuration 730 of FIG. 7 can be eliminated. Electrical interconnection 785 makes contact with one or more of the array of conductive vias 770, which are maintained at the AC ground potential of the ground plane 790. Electrical interconnection 785 is terminated by the active circuit configuration 730, which is now at the AC ground potential as well.

While the preferred embodiments to the invention have been described, it will be understood that those skilled in the art, both now and in the future, may make various improvements and enhancements which fall within the scope of the claims which follow. These claims should be construed to maintain the proper protection for the invention first described.

What is claimed is:

1. A structure for shielding high frequency passive elements disposed above substrates comprising:
a semi-conductive substrate configured for integrated circuit formation therein, said semi-conductive substrate having a first and a second face, said second face being disposed substantially parallel to said first face;
a non-conductive substrate having a first and a second face, said second face being disposed substantially parallel to said first face, said non-conductive substrate being placed on top of said conductive substrate; and
the first face of said semi-conductive substrate in parallel contact with the second face of said non-conductive substrate;
a passive element disposed in said non-conductive substrate and isolated from said second face of said non-conductive substrate;
an electronic circuit disposed in said semi-conductive substrate;
a plurality of conductive conduits disposed in said semi-conductive substrate extending from said first face to said second face of said semi-conductive substrate, each said conductive conduit being isolated from said neighboring conductive conduits by the material comprising said semi-conductive substrate and disposed substantially beneath said passive element;
a ground plane disposed on said second face of said semi-conductive substrate, the ground plane electrically connecting said conductive conduits disposed in said semi-conductive substrate; and
an electrical connection between said electronic circuit, said passive element and said ground plane, such that said passive device and said ground plane are held at different electrical potentials.

2. The structure of claim 1 wherein said semi-conductive substrate has a restivity of about 0.1 Ohm-cm to about 100 Ohm-cm.

3. The structure of claim 1 wherein said conductive conduits each have a one of a substantially circular cross-section and a square cross-section.

4. The structure of claim 3 wherein said conductive conduits cross-sections have a solid conductive core.

5. The structure of claim 3 wherein said conductive conduits have conductively coated sidewalls with a hollow cross-section.

6. The structure of claim 3 wherein said conductive conduit smallest cross-section dimension ranges from about 1 um to about 5 um in diameter.

7. The structure of claim 3 wherein said conductive conduits comprise an array with substantially constant spacing between said conductive conduits, said array disposed substantially beneath said passive element.

8. The structure of claim 3 wherein said conductive conduits comprise an array with substantially constant spacing between said conductive conduits, said array disposed substantially beneath said passive element and extending beyond the boundaries of said passive element by about 5 um.

9. The structure of claim 3 wherein said conductive conduits comprise an array with varying spacing between said conductive conduits; and
wherein said array is substantially beneath said passive element.

10. The structure of claim 3 wherein said conductive conduits comprise an array with varying spacing between said conductive conduits;
wherein said array is substantially beneath said passive element and extends beyond the boundaries of said passive element by about 5 um; and
wherein said array has its most closely spaced conductive conduits substantially beneath portions of said passive element being most sensitive to electric field coupling between said passive element and said semi-conductive substrate.

11. The structure of claim 1 wherein said conductive conduits each have a one of a substantially oblong cross-section and a rectangular cross-section.

12. The structure of claim 1 wherein said conductive conduits each have a one of a substantially oblong cross-section and a rectangular cross-section such that the long dimension of said conductive conduits does not exceed about ½ the long dimension of said passive element; and
wherein a short dimension of said conductive conduits ranges from about 1 um to about 5 um.

13. The structure of claim 12 wherein said passive element comprises at least one of the following: inductor; transformer; and other magnetically coupled elements.

14. The structure of claim 13 wherein said conductive conduits are arranged beneath said passive element; and
wherein said conductive conduits have a longest dimension thereof substantially perpendicular to the direction of current flow in said passive element.

15. The structure of claim 1 wherein said conductive conduits each have a one of a substantially oblong cross-section and a rectangular cross-section such that the long dimension of said conductive conduits exceeds the long dimension of said passive element by about 5 um; and
wherein a short dimension of said conductive conduits ranges from about 1 um to about 5 um.

16. The structure of claim 15 wherein said passive element comprises at least one of the following: inductor; transformer; and other magnetically coupled elements; and
wherein said passive element is connected to said electronic circuit such that the potential on a first terminal of said passive element is about 180 degrees out of phase with the potential on a second terminal of said passive device.

17. The structure of claim 16 wherein said passive element is constructed such that the impedance of said first terminal is substantially equal to the impedance of said second terminal; and
wherein a line of symmetry exists through a centerline of said passive element.

18. The structure of claim 17 wherein said conductive conduits are arranged substantially beneath said passive element; and
wherein said conductive conduits having their longest dimension substantially perpendicular to said line of symmetry of said passive element.

19. The structure of claim 1 wherein said conductive conduits provide ground potential to said electronic circuit.

20. A method for shielding high frequency passive elements disposed above a conductive substrate, the method comprising:
forming a semi-conductive substrate configured for integrated circuit formation therein, the semi-conductive substrate having a first and a second face, the second face being disposed substantially parallel to said first face;
forming a plurality of conductive conduits disposed in the semi-conductive substrate that extend from the first face to the second face of the semi-conductive substrate, with each of the conductive conduits being isolated from the neighboring conductive conduits by the material comprising the semi-conductive substrate;
forming an integrated circuit in the semi-conductive substrate;
forming a non-conductive substrate having a first and a second face, the second face being disposed substantially parallel to said first face;
disposing the non-conductive substrate on top of the semi-conductive substrate, wherein the first face of the semi-conductive substrate is in parallel contact with the second face of the non-conductive substrate;
disposing a passive element in the non-conductive substrate so as to be isolated from the second face of the non-conductive substrate, wherein the passive element is substantially above the plurality of conductive conduits;
forming a metal layer ground plane disposed on the second face of the semi-conductive substrate, the ground plane electrically connecting the conductive conduits disposed in the semi-conductive substrate; and
forming an electrical connection between the electronic circuit, the passive element and the metal layer ground plane, such that the passive element and the second metal ground plane are held at different electrical potentials.
